(19) United States
(12) Patent Application Publication
(10) Pub. No.: US 2024/0202424 A1
(43) Pub. Date: Jun. 20, 2024

(54) METHOD OF CORRECTING DESIGN LAYOUT OF SEMICONDUCTOR DEVICE, COMPUTING DEVICE PERFORMING THE SAME, AND METHOD OF FABRICATING SEMICONDUCTOR DEVICE USING THE SAME

(71) Applicant: Samsung Electronics Co., Ltd., Suwon-si (KR)

(72) Inventors: Jichang SIM, Suwon-si (KR); Ohhun KWON, Suwon-si (KR); Hyuckjoon KWON, Suwon-si (KR); Bok-Yeon WON, Suwon-si (KR)

(73) Assignee: Samsung Electronics Co., Ltd., Suwon-si (KR)

(21) Appl. No.: 18/335,428

(22) Filed: Jun. 15, 2023

(30) Foreign Application Priority Data
Dec. 14, 2022 (KR) 10-2022-0175251

(51) Int. Cl. G06F 30/398; G06F 30/392

(52) U.S. Cl. CPC G06F 30/398; G06F 30/392

(57) ABSTRACT

A computing device separates a first target layer including a plurality of target patterns from an original design layout, shifts the plurality of target patterns in the first target layer based on misalignment values at positions of the plurality of target patterns to generate a second target layer, and combines the second target layer with the original design layout from which the first target layer is separated to generate a corrected design layout.

### CROSS-REFERENCE TO RELATED APPLICATION

This U.S. non-provisional application claims the benefit of priority under 35 U.S.C. § 119 to Korean Patent Application No. 10-2022-0175251 filed in the Korean Intellectual Property Office on Dec. 14, 2022, the entire contents of which are incorporated herein by reference.

### BACKGROUND

### (a) Field

The disclosure relates to a method of correcting a design layout of a semiconductor device, a computing device for performing the same, and a method of fabricating a semiconductor using the same.

### (b) Description of the Related Art

In designing an integrated circuit, a design layout of a circuit may be produced to form a desired circuit on a semiconductor substrate and be transferred to a wafer surface through a mask. As semiconductor devices become more highly integrated, circuit design may become more complex. If a misalignment occurs in a semiconductor device fabricated according to a design layout, a gap between two misaligned patterns may be narrow such that an insulating film surrounding the two patterns may be destroyed or otherwise experience a degradation in performance.

### SUMMARY

Some example embodiments may provide a method of correcting a design layout of a semiconductor device, a computing device for performing the same, and a method of fabricating a semiconductor using the same, for correcting misalignments in a design layout.

According to some example embodiments, the inventive concepts may provide a method of correcting a design layout of a semiconductor device, performed by a computing device. The method may include separating a first target layer comprising a plurality of target patterns from an original design layout, generating a second target layer by shifting the plurality of target patterns in the first target layer based on misalignment values at respective positions of the plurality of target patterns, respectively, and combining the second target layer with the original design layout from which the first target layer is separated to generate a corrected design layout.

According to some example embodiments, the inventive concepts may provide a computing device, the computing device may comprise a memory configured to store one or more instructions, and one or more processors configured to execute the one or more instructions. The one or more processors may be configured, by executing the one or more instructions, to separate a target layer including a plurality of target patterns from a design layout of a semiconductor device, shift the plurality of target patterns in the target layer based on misalignment values at the plurality of target patterns, and combine the target layer in which the plurality of target patterns are shifted with the design layout from which the target layer is separated to generate a corrected design layout.

According to some example embodiments, the inventive concepts may provide a method of fabricating a semiconductor device. The method may include loading an original design layout, separating a target layer comprising a plurality of target patterns from the original design layout, shifting the plurality of target patterns in the target layer based on misalignment values, combining the target layer in which the plurality of target patterns are shifted with the original design layout from which the target layer is separated to generate a corrected design layout, manufacturing a mask based on the corrected design layout, and fabricating a semiconductor device based on the mask.

### BRIEF DESCRIPTION OF THE DRAWINGS

FIG. 1 is a block diagram illustrating at least one example embodiment of a semiconductor inspection system.

FIG. 2 is a diagram illustrating at least one example embodiment of a method of correcting a design layout of a semiconductor device.

FIG. 3 is a block diagram illustrating at least one example embodiment of a memory device.

FIG. 4 is a block diagram illustrating at least one example embodiment of a core region of the memory device shown in FIG. 3.

FIG. 5 is a circuit diagram illustrating at least one example embodiment of the sub-wordline driver shown in FIG. 4.

FIG. 6 is a diagram illustrating at least one example embodiment of a layout of the sub-wordline driver shown in FIG. 4.

FIG. 7 is a cross-sectional view illustrating a cross-section along A-A′ of the layout structure shown in FIG. 6.

FIG. 8 is a diagram illustrating an example of a misalignment in FIG. 7.

FIG. 9 is a diagram illustrating at least one example embodiment of a target layer extracted from the layout shown in FIG. 6.

FIG. 10 is a flow diagram illustrating at least one example embodiment of a misalignment value estimation method in a design layout correction method.

FIG. 11 is a diagram the misalignment value estimation method shown in FIG. 10.

FIG. 12 is a flowchart illustrating at least one example embodiment of a design layout correction method.

FIG. 13 is a flowchart illustrating at least one example embodiment of a method of fabricating a semiconductor device.

FIG. 14 is a block diagram illustrating at least one example embodiment of a computing device.

### DETAILED DESCRIPTION

In the following detailed description, some example embodiments of the present invention have been shown and described, but the inventive concepts are not limited thereto. Those of ordinary skill in the art would realize that the described embodiments may be modified in various different ways without departing from the spirit or scope of the inventive concepts described herein.

Accordingly, the drawings and description are to be regarded as illustrative in nature and not restrictive. Like reference numerals designate like elements throughout the specification. The sequence of operations or steps is not limited to the order presented in the claims or figures unless specifically indicated otherwise. For example, unless expressly indicated otherwise, the order of operations or steps may be changed, several operations or steps may be merged, a certain operation or step may be divided, and a specific operation or step may not be performed. Furthermore, the sizes of elements may be exaggerated for clarity and/or convenience of explanation.

As used herein, the singular forms “a” and “an” are intended to include the plural forms as well, unless the context clearly indicates otherwise. Likewise, the terms “the” and similar instruction terms may correspond to both singular and plural. Although the terms first, second, and the like may be used herein to describe various elements, components, steps and/or operations, these terms are only used to distinguish one element, component, step or operation from another element, component, step, or operation and should not be interpreted to limit the described example embodiments.

Hereinafter, what is referred to as “above” or “on” may include not only directly in a contact manner but also in a non-contact manner.

In addition, the terms “unit”, “module” or the like means a unit for processing at least one function or operation, which can be implemented in hardware or software or a combination of hardware and software.

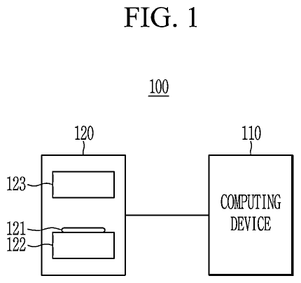

FIG. 1 is a block diagram illustrating at least one example embodiment of a semiconductor inspection system.

Referring to FIG. 1, a semiconductor inspection system 100 may include a computing device 110 and an image detection device 120.

The image detection device 120 may include a chuck 122 into which a wafer 121 is loaded and include an image measurement device 123 that acquires an image of patterns formed on a substrate of the wafer 121. In an example embodiment, the image measurement device 123 may acquire the image using a source such as an electron beam. For example, in some example embodiments, the image measurement device 123 may be a scanning electron microscope (SEM) such as a high voltage (HV) SEM, but is not limited thereto.

The computing device 110 may measure a misalignment (M/A) value of a target pattern on the wafer 121 based on an image acquired by the image measurement device 123. For example, in at least one example embodiment, the computing device 110 may obtain misalignment values of a plurality of target patterns on the wafer 121 based on an image of patterns formed on the wafer 121 that may be fabricated based on an original design layout of the wafer 121. The computing device 110 may further correct a misalignment of the plurality of target patterns in the original design layout based on the misalignment values of the plurality of target patterns. For example, the computing device 110 may use the image measurement device 123 to measure the misalignment values of the target patterns included in some regions among a plurality of regions including remaining target patterns of the original design layout on the wafer 121, and the computing device 110 may estimate misalignment values for the remaining target patterns among the plurality of regions in the original design layout based on the measured misalignment values in the some regions. In some example embodiments, the computing device 110 may separate a target layer including the plurality of target patterns from the original design layout, shift the plurality of target patterns included in the target layer based on the misalignment values at the respective positions of each of the plurality of target patterns, and combine the target layer that is generated by shifting the target patterns in the target layer with the original design layout from which the target layer is separated in order to generate a corrected design layout. The misalignment value at the respective position of each of the plurality target patterns may be the misalignment value in the corresponding region of the original design layout including the respective target pattern.

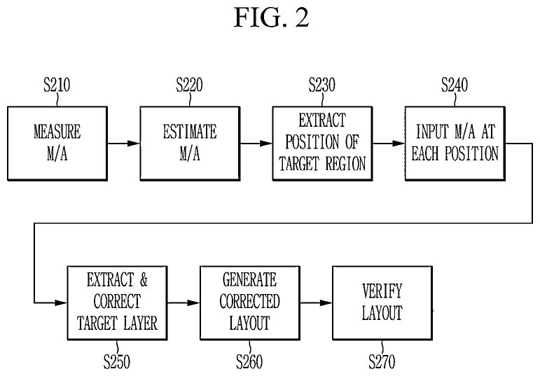

FIG. 2 is a diagram illustrating at least one example embodiment of a method of correcting a design layout of a semiconductor device.

Referring to FIG. 1 and FIG. 2, in some example embodiments, in S210 and S220, a computing device 110 may obtain misalignment values on wafer 121 using an image measurement device 123. In some example embodiments, in S210, the computing device 110 may use the image measurement device 123 to obtain an image of some regions among a plurality of regions on the wafer 121, and may measure misalignment values in the some regions based on the image acquired. In some example embodiments, in S220, the computing device 110 may use an interpolation model to estimate misalignment values in remaining unmeasured regions among the plurality of regions based on the misalignment values in the some regions. In some example embodiments, the wafer 121 may be a wafer that is taped out with a mask. The mask may have an original design layout whose misalignment values are to be corrected applied thereto. In some example embodiments, the wafer 121 may be a wafer for the same generation product as the original design layout. In some example embodiments, the some regions may be regions adjacent to a peripheral region or a scribe lane in a semiconductor die on the wafer 121. The peripheral region may be a region where circuit elements are formed that perform reading or writing operations of the memory cell. The scribe lane may be a spacing that separates semiconductor dies.

In some example embodiments, the misalignment value of a region may be a value measured between a point on a target pattern included in the region and a point on a counterpart pattern. For example, the misalignment value for each region may be a misalignment value between a point on the target pattern included in the respective region and a point on a counterpart pattern. The counterpart pattern may be a pattern used to determine whether the target pattern is misaligned and may be obtained, for example, from an original design layout used in fabricating wafer 121. In some example embodiments, the computing device 110 may measure the misalignment value for a region based on a distance between the point on the target pattern included in the region and the point on the counterpart pattern. In some example embodiments, when the distance between the point on the target pattern and the point on the counterpart pattern is less than a predetermined (or alternatively, desired) distance, the misalignment value may be a value indicating a difference between the predetermined (or alternatively, desired) distance and the distance between the point on the target pattern and the point on the counterpart pattern. Although, the misalignment value is described with reference to a predetermined (or alternatively, desired) distance, the misalignment value should not be limited thereto. For example, the misalignment value may be a value indicating a difference between a distance that is determined and the distance between the point on the target pattern and the point on the counterpart pattern.

In some example embodiments, in S230, the computing device 110 may extract positions of a plurality of target regions from the original design layout. The plurality of target regions may be regions including the target pattern. In some example embodiments, the plurality of target regions may be semiconductor cells. The positions of the plurality of target regions may include, for example, coordinates of each target region. In some example embodiments, the computing device 110 may further extract information of the plurality of target regions that indicates which semiconductor cell each of the plurality of target regions is in. The information of the plurality of target regions may include, for example, information that indicates a sub-wordline driver each of the plurality of target regions corresponds to.

In some example embodiments, in S240, the computing device 110 may input the misalignment values of the plurality of regions obtained from the wafer 121 as misalignment values in a plurality of target regions that have the positions respectively corresponding to the plurality of regions. Thus, even though target patterns included in different target regions may have different degrees of misalignment, the misalignment value corresponding to the position of each target region may be input. In some example embodiments, the computing device 110 may determine a correction value for each of the plurality of target regions based on the misalignment values in the plurality of target regions, and input the correction values. In some example embodiments, the computing device may generate data including the position of each of the plurality of target regions and the misalignment value at that position. In some example embodiments, the computing device may generate data including the position of each of the plurality of target regions and the correction value at that respective position. In some example embodiments, the correction value may be a value that offsets the misalignment of the respective target region. For example, the correction value may be a value that corrects the misalignment of the respective target region in a direction that is opposite to a direction of the misalignment.

In some example embodiments, in S250, the computing device 110 may extract a target layer including target patterns of the target regions from the original design layout, and correct the misalignment of the plurality of target patterns by shifting each of the plurality of target patterns in the target layer based on the respective misalignment value. Accordingly, each target pattern may be shifted based on the misalignment value at the respective position of the target pattern (e.g., the misalignment value in the target region corresponding to the position of the target pattern) even if the misalignment value of the plurality of target patterns varies depending on the respective positions of the plurality of target regions. In some example embodiments, the computing device 110 may shift the plurality of target patterns in the target layer by the correction values of the respective target region in a direction that offsets the misalignment. In some example embodiments, in S250, the computing device 110 may shift each target pattern included in the plurality of target regions of the original design layout together based on the data generated in S240. In some example embodiments, in S250, the computing device may generate a new semiconductor cell by separating the target layer including the plurality of target regions and shift the target patterns in the generated semiconductor cell. Generating the new semiconductor cell with the target layer may facilitate subsequent optical proximity correction.

In some example embodiments, in S260, the computing device 110 may combine the target layer (e.g., a semiconductor cell) in which the plurality of target patterns of the target regions are shifted with the original design layout from which the target layer is separated to generate a corrected design layout. In some example embodiments, in S260, the computing device 110 may generate the corrected design layout by disposing the shifted semiconductor cell in a top cell of the original design layout from which the target layer is extracted. Disposing the shifted semiconductor cell in the top cell may facilitate verification of the shifted semiconductor cell.

In some example embodiments, in S270, the computing device 110 may verify the corrected design layout. In some example embodiments, the computing device 110 may verify that the number of the plurality of target patterns in the corrected design layout is equal to the number of the plurality of target patterns in the original design layout. For example, the computing device 110 may verify the corrected design layout by comparing the number of the plurality of target patterns in the corrected design layout with the number of the plurality of target patterns in the original design layout. In some example embodiments, the computing device 110 may verify that the plurality of target patterns are shifted by the correction values based on a shift value between each of the plurality of target patterns in the corrected design layout and a corresponding one of the plurality of target patterns in the original design layout.

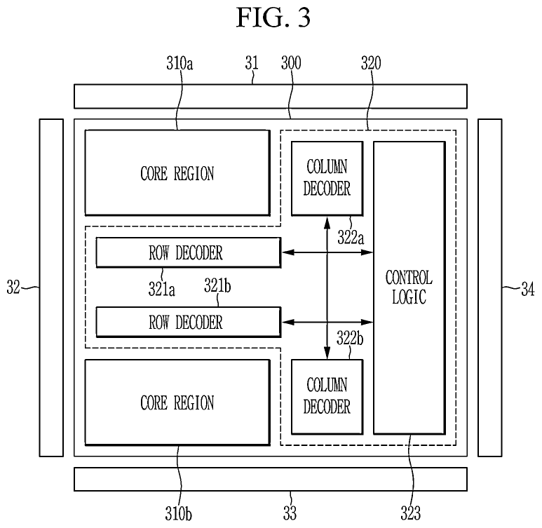

Next, an example of a target region to which a design layout correction method according to some example embodiments is applied is described with reference to FIGS. 3 to 8. Although FIGS. 3 to 8 are described below with reference to a sub-wordline driver included in a core region of a memory device, the description of FIGS. 3 to 8 is not limited thereto and may be used to correct other design layouts.

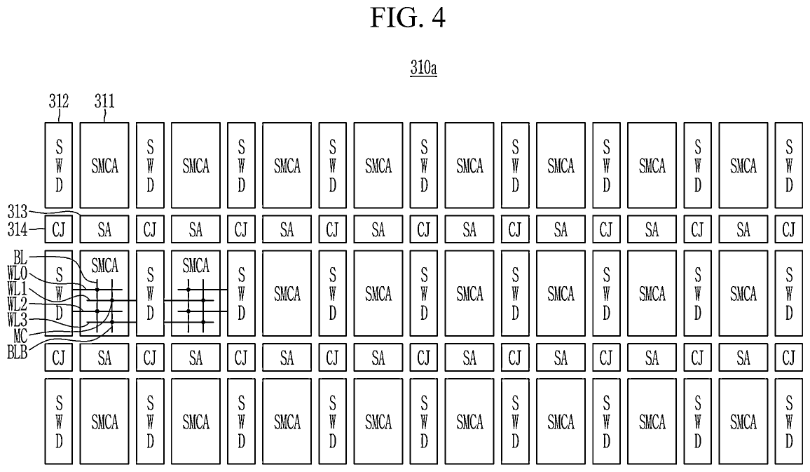

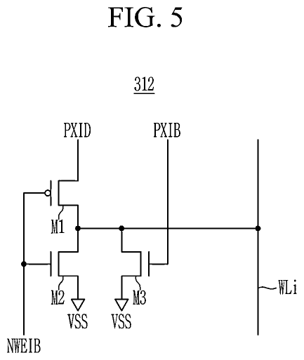

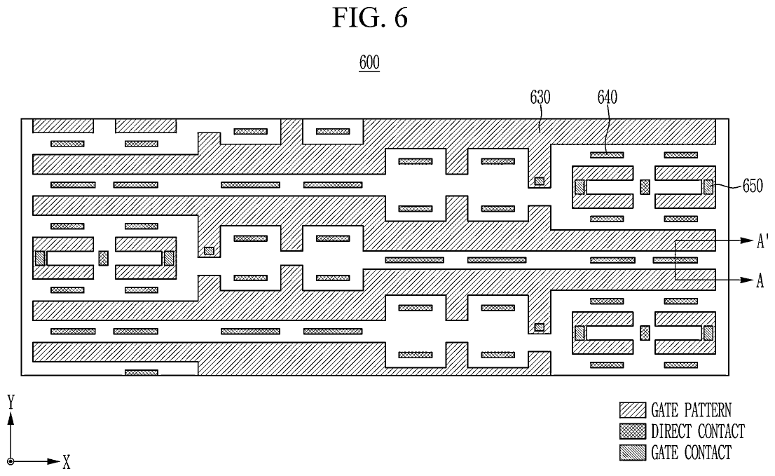

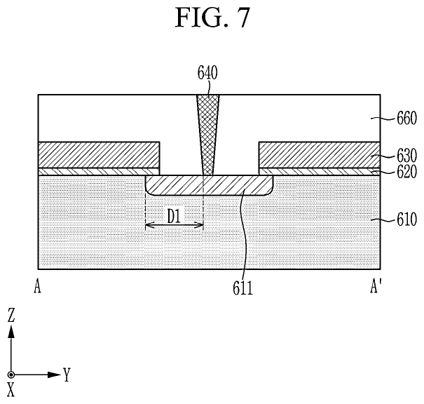

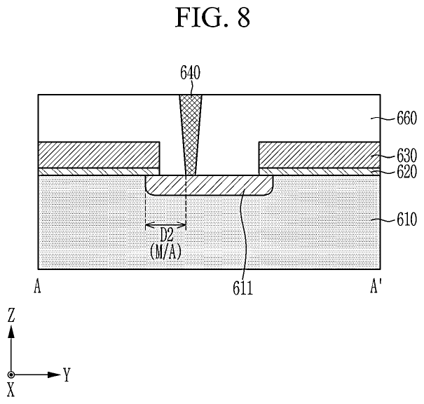

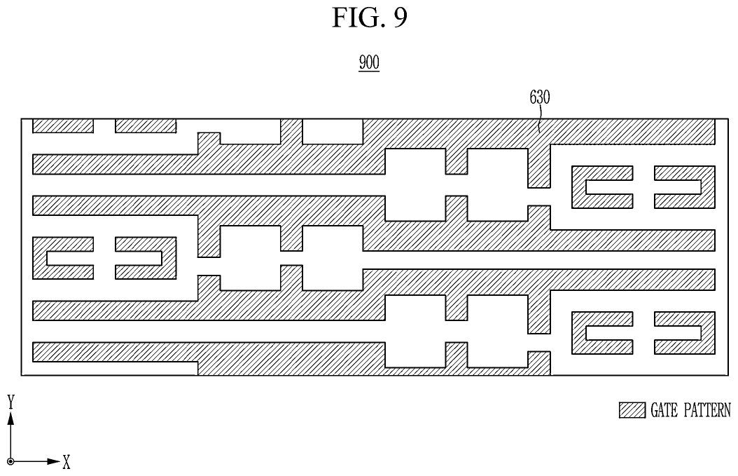

FIG. 3 is a block diagram illustrating an example of a memory device according to some example embodiments, FIG. 4 is a block diagram illustrating an example of a core region of a memory device shown in FIG. 3, FIG. 5 is a circuit diagram illustrating an example of a sub-wordline driver shown in FIG. 4, FIG. 6 is a diagram illustrating an example of a layout of a sub-wordline driver shown in FIG. 4, FIG. 7 is a cross-sectional view illustrating an A-A′ cut in a layout structure shown in FIG. 6, FIG. 8 is a diagram illustrating an example of a misalignment occurrence in FIG. 7, and FIG. 9 is a diagram illustrating an example of a target layer extracted from a layout shown in FIG. 6.

Referring to FIG. 3, in some example embodiments, a memory device 300 may include core regions 310a and 310b, and a peripheral region 320. Although FIG. 3 shows two core regions 310a and 310b for convenience, the number of core regions 310a and 310b are not limited thereto. For example, the number of core regions 310a and 310b may be more than two or less than two. In some example embodiments, the memory device 300 may be formed on a semiconductor die. The semiconductor die may be formed on a wafer and may be separated from other semiconductor dies on the wafer by scribe lanes 31, 32, 33, and 34. Although FIG. 3 shows four scribe lanes 31, 32, 33 and 34, the number of scribe lanes 31, 32, 33 and 34 should not be limited thereto. For example, the number of scribe lanes may be more than four or less than four.

Referring to FIG. 4, in some example embodiments, the core region 310a may include a plurality of sub-memory cell arrays (SMCAs) 311, a plurality of sub-wordline drivers (SWDs) 312, a plurality of sense amplifiers (SAs) 313, and a plurality of conjunctions (CJs) 314.

The plurality of sub-memory cell arrays 311 may be arranged in a row direction (e.g., a wordline direction) and a column direction (e.g., a bitline direction). Each sub-memory cell array 311 may include a plurality of memory cells MC. The plurality of memory cells MC may be disposed at intersections of a plurality of wordlines WL0, WL1, WL2, and WL3 and a plurality of bitlines BL and BLB, respectively.

Each sub-wordline driver 312 may be disposed between the sub-memory cell arrays 311 which neighbor each other in the row direction. In some example embodiments, the sub-memory cell arrays 311which neighbor each other in the row direction may share the same sub-wordline driver 312 therebetween. For example, as illustrated in FIG. 4, the sub-wordline driver 312 may drive the corresponding wordlines WL0 to WL3 of the corresponding sub-memory cell arrays 311 that it is between. Although FIG. 4, for convenience, shows that the sub-memory cell arrays 311 include the four wordlines WL0 to WL3, the number of wordlines WL0 to WL3 is not limited thereto. For example, the number of wordlines WL0 to WL3 may be more than four or less than four. In some example embodiments, when the sub-wordline driver 312 drives the four wordlines WL0 to WL3, the sub-wordline driver 311 may include four sub-wordline driving circuits.

Each sense amplifier 313 may be disposed between the sub-memory cell arrays 311 which neighbor each other in the column direction. The sub-memory cell arrays 311 neighboring in the column direction may share the sense amplifier 313 disposed therebetween. The sense amplifier 313 may sense data in the corresponding sub-memory cell array 311. The sense amplifier 313 may sense the data from bitlines BL and BLB of the corresponding sub-memory cell array 311.

The conjunctions 314 may be disposed at intersections of the sub-wordline drivers 312 and the sense amplifiers 313. The conjunctions 314 may include a driver that drives the corresponding sub-wordline driver 312 and the corresponding sense amplifier 313.

Referring to FIG. 3, the peripheral region 320 may include circuits and/or logic for performing read or write operations of the memory cells. In some example embodiments, the peripheral region 320 may include, for example, row decoders 321a and 321b, column decoders 322a and 322b, and control logic 323. The control logic 323 may generate a control signal to cause the memory device 300 to perform a memory operation such as a read operation or a write operation. The row decoders 321a and 312b may select a row (e.g., wordline) to be activated from a plurality of rows of the memory cells in the core regions 310a and 310b in response to the control signal from the control logic 323. The column decoders 322a and 322b may select a column (e.g., bitline) to be activated from a plurality of columns in the memory cells of the core regions 310a and 310b in response to the control signal from the control logic 323.

Referring to FIG. 5, in some example embodiments, each sub-wordline driving circuit of the sub-wordline driver 312 may include transistors M1, M2, and M3. The transistor M1 may be a p-channel metal oxide semiconductor (PMOS) transistor, and the transistors M2 and M3 may be n-channel metal oxide semiconductor (NMOS) transistors. A source of the transistor M1 may be connected to a line that transfers a drive signal PXID of a wordline WLi to which the corresponding sub-wordline driving circuit is connected. Sources of the transistors M2 and M3 may be connected to a power source VSS. Drains of the transistors M1, M2, and M3 may be connected to the wordline WLi. The power source VSS may be a terminal having a potential corresponding to a logic low level, for example, a ground terminal. An enable signal NWEIB may be applied to gates of the transistors M1 and M2, and a drive signal PXIB may be applied to the gate of transistor M3. Thus, the sub-wordline driver 312 may drive the wordline WLi based on logic levels of the enable signal NWEIB and the drive signals PXID and PXIB.

Referring to FIG. 6, in some example embodiments, an original design layout 600 of the sub-wordline driver 312 may include gate patterns 630, direct contacts 640, and gate contacts 650. Each gate contact 650 may be connected to a corresponding gate pattern 630 and an electrode (not shown) that carries a gate signal. For convenience, FIG. 6 shows only the gate patterns 630 and contacts 640 and 650 without showing other structures in the sub-wordline driver 312 and is not limited to the features shown therein.

Referring to FIGS. 6 and 7, a doping region 611 may be disposed in a substrate 610. If a region shown in FIG. 7 forms an NMOS transistor (e.g., M3 in FIG. 5), the substrate 610 may be a P-type substrate and the doping region 611 may be an N+ doping region 611. A gate insulating film 620 may be disposed on the substrate 610, and the gate pattern 630 may be disposed on the gate insulating film 620. The direct contact 640 may be disposed on the doping region 611. The direct contact 640 may be connected to the doping region 611 and an electrode (not shown) that carries a drive signal. Additionally, an interlayer insulating film 660 may be disposed on the substrate 610 to enclose the gate insulating film 620, the gate pattern 630, and the direct contact 640. The doping region 611 may form, for example a drain of transistor M3, and the direct contact 640 disposed on the doping region 611 may be connected to a wordline (e.g., WLi in FIG. 5).

If the gate pattern 630 and the direct contact 640 are misaligned (M/A) in the original design layout 600, a distance D2 between the gate pattern 630 and the direct contact 640 may become shorter than a distance D1 between the gate pattern 630 and the direct contact 640 when the misalignment does not occur, as shown in FIGS. 7 and 8. When the distance between the gate pattern 630 and the direct contact 640 is shorter than the distance D1, the misalignment value may be, for example, (D2-D1). Because a high drive voltage is applied to the sub-wordline driver 312, if the gate pattern 630 and the direct contact 640 in the sub-wordline driver 312 become too close, the insulating film 660 between the gate pattern 630 and the direct contact 640 may be destroyed or experience a degradation in performance. Accordingly, as shown in FIG. 9, a computing device may separate a target layer 900 including the gate patterns 630 of the subword driver 312 from the design layout 600 of the memory device, and correct the target layer 900 by shifting the gate patterns 630 in the target layer 900 by a correction value at a position of the gate patterns 630 (e.g., (D1-D2)) in a positive direction along the Y-axis. Further, the computing device may combine the shifted target layer with the design layout from which the target layer 900 is separated to correct the design layout.

While FIGS. 3 to 9 show the gate pattern 630 of the sub-wordline driver 312 as an example of a target pattern, the target pattern is not limited thereto.

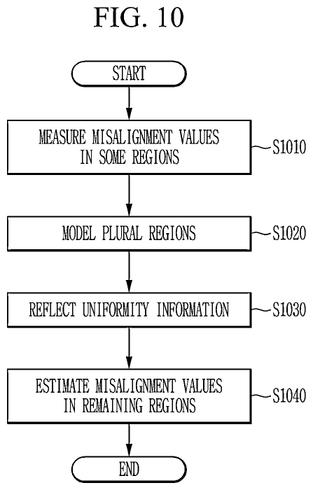

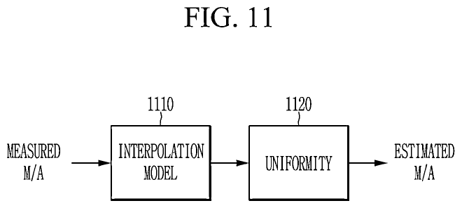

FIG. 10 is a flow diagram illustrating an example embodiment of a misalignment value estimation method in a design layout correction method according to some example embodiments, and FIG. 11 is a diagram for illustrating at least one example embodiment of a misalignment value estimation method shown in FIG. 10.

Referring to FIG. 10, in S1010, a computing device may measure misalignment values of target patterns included in some regions among a plurality of regions on a wafer using an image measurement device. In some example embodiments, the wafer may be a wafer that is taped out with a mask having an original design layout applied thereto. In some example embodiments, the wafer may be a wafer for the same generation product as the original design layout. In some example embodiments, the some regions may be a predetermined (or alternatively, desired) number of regions adjacent to a peripheral region (e.g., 320 in FIG. 3) and/or scribe lanes (e.g., 31 to 34 in FIG. 3) among a plurality of regions included in core regions (e.g., 310a and 310b in FIG. 3) of a memory device formed on a semiconductor die. In some example embodiments, the plurality of regions may be regions in which sub-wordline drivers 312 are formed in the core regions 310a and 310b.

In S1020, the computing device may model unmeasured target patterns among the plurality of regions based on the measured misalignment values of the target patterns in the some regions. In some example embodiments, as shown in FIG. 11, the computing device may model the plurality of unmeasured target patterns among the plurality of regions based on the measured misalignment values in the some regions to generate an interpolation model 1110. The computing device may perform the modelling on a line-by-line basis. For example, for each row or each column, the computing device may generate the interpolation model 1110 depending on a distance from the regions including measured target patterns based on the misalignment values of the measured target patterns in the some regions in the corresponding row or corresponding column. In some example embodiments, the interpolation model 1110 may be a model using regression analysis such as a linear model or a non-linear model. In some example embodiments the interpolation model 1110 may be a machine learning model. The machine learning module, may, for example, use various artificial neural network organizations and processing models, the artificial neural network organizations including, for example, a convolutional neural network (CNN), a deconvolutional neural network, a recurrent neural network optionally including a long short-term memory (LSTM) and/or a gated recurrent unit (GRU), a stacked neural network (SNN), a state-space dynamic neural network (SSDNN), a deep belief network (DBN), a generative adversarial network (GAN), and/or a restricted Boltzmann machine (RBM), and/or the like; and/or include linear and/or logistic regression, statistical clustering, Bayesian classification, decision trees, and/or the like.

In some example embodiments, in S1040, the computing device may use the interpolation model 1110 to estimate misalignment values of remaining unmeasured target patterns in the remaining unmeasured regions based on distances of the remaining unmeasured regions from the measured regions.

In some example embodiments, the computing device may use the interpolation model 1110 to calculate initial misalignment values of the target patterns in the remaining unmeasured regions and reflect uniformity information 1120 on the wafer into the initial misalignment values of the target patterns in S1030, thereby estimating final misalignment values for the remaining unmeasured target patterns included in the remaining unmeasured regions in S1040. The uniformity in the wafer may include, for example, in-chip uniformity (ICU), in-field uniformity (IFU), and/or in-wafer uniformity (IWU). For example, when generating the interpolation model 1110 within the same semiconductor die, the computing device may correct the misalignment values calculated by the interpolation model 1110 to reflect the ICU within the semiconductor die into the misalignment values. In another example, when generating the interpolation model 1110 across a plurality of semiconductor dies, the computing device may correct the misalignment values calculated by the interpolation model 1110 by reflecting the ICU, IFU, and/or IWU into the misalignment values.

According to the above-described embodiments, the computing device may estimate misalignment values of the target patterns in the plurality of regions based on the misalignment values measured in some regions without having to measure the misalignment values in all regions.

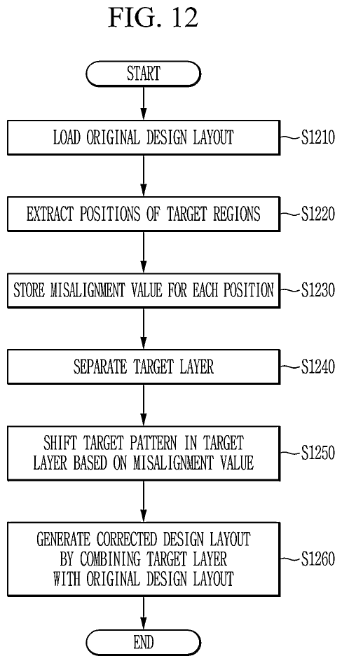

FIG. 12 is a flowchart illustrating an example of a design layout correction method according to some example embodiments.

Referring to FIG. 12, in some example embodiments, in S1210, a computing device may receive an original design layout. In some example embodiments, the computing device may load the original design layout stored in a storage device. In S1220, the computing device may extract positions of each of a plurality of target regions having an original design layout (e.g., original design layout 600 in FIG. 6) from the core region 310a. The plurality of target regions of the core region 310a having the original design layout 600 may include, for example, sub-wordline driver blocks (e.g., sub-wordline driver cells) (e.g., sub-wordline driver 312 in FIG. 4). In some example embodiments, the positions of a target region in the original design layout 600 may be coordinates of the target region in the original design layout 600.

In some example embodiments, S1230, the computing device may store, for the position of each of the plurality of target regions having the original design layout 600, a misalignment value of the target patterns of the corresponding target region having the original design layout 600. The misalignment value of the target pattern of the target region having the original design layout 600 may be the misalignment value of gate pattern 630 estimated in S1040 of FIG. 10 and included in a region corresponding to the position of the target region. In some example embodiments, the computing device may store data in which the position of each target region is mapped with the misalignment value of the corresponding target region. In some example embodiments, the computing device 110 may store data in which the position of each gate pattern 630 of each target region is mapped with the misalignment value of the corresponding target region. In some example embodiments, the computing device may determine a correction value for each of the target regions based on the misalignment value in the respective target region and store the correction values along with the misalignment values in S1230. In some example embodiments, in S1230, the computing device may store data in which the position of each target region is mapped with the correction value of the corresponding target region. In some example embodiments, the computing device may store data in which the position of each target region is mapped with the correction value of the corresponding target pattern.

In some example embodiments, in S1240, the computing device may separate a target layer (e.g., 900 in FIG. 9) including target patterns (e.g., gate pattern 630 in FIG. 6) of the target regions from the original design layout 600 of the target regions. In some example embodiments, the computing device may generate the separated target layer 900 as a new semiconductor cell.

In S1250, the computing device may correct the misalignment by shifting the target patterns 630 in the target layer 900, or new semiconductor cell, based on misalignment values mapped to the positions of the respective target regions, or the respective positions of the target patterns. In some example embodiments, the computing device 110 may shift the target patterns of the target layer 900 of a plurality of target regions 312 together based on the data generated at S1230. In some example embodiments, the computing device 110 may shift the target patterns by the misalignment values in a direction that offsets the misalignment. In some example embodiments, the computing device may shift the target patterns by the correction values. For example, if the misalignment occurs in the structure shown in FIG. 7 as shown in FIG. 8, the misalignment value may be, for example, (D2-D1). Accordingly, the computing device may correct the misalignment by shifting the target pattern 630 of the target layer 900 shown in FIG. 9 along the positive Y-axis direction by, for example, (D1-D2), based on the misalignment value.

In some example embodiments, in S1260, the computing device may combine the shifted target layer with the original design layout from which the target patterns are separated to generate a corrected design layout. In some example embodiments, the computing device may generate the corrected design layout by disposing the semiconductor cell, in which the target patterns are shifted, in a top cell of the original design layout from which the target layer is separated in.

According to the above-described embodiments, the computing device may shift the target patterns in the target layer based on the misalignment values corresponding to the positions of the target patterns, thereby allowing correction of the design layout without manual modification of cells by, for example, a layout engineer.

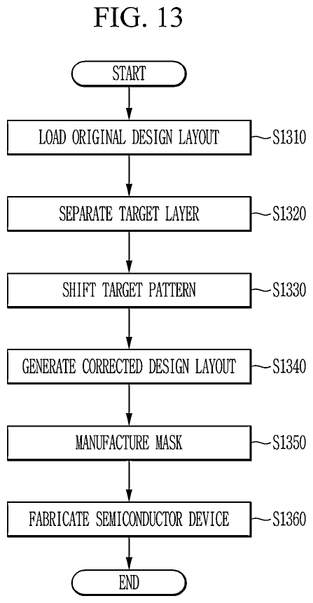

FIG. 13 is a flowchart illustrating at least one example embodiment of a method of fabricating a semiconductor device.

Referring to FIG. 13, in some example embodiments, a method of fabricating a semiconductor device may include loading an original design layout of a semiconductor device in S1310, separating a target layer including a plurality of target patterns from the original design layout in S1320, shifting the target patterns in the target layer based on misalignment values in S1330, generating a corrected design layout by combining the shifted target layer with the original design layout from which the target layer is separated in S1340, manufacturing a mask based on the corrected design layout in S1350, and fabricating a semiconductor device based on the mask in S1360.

In some example embodiments, the original design layout may be provided from a computing device at a semiconductor fabricating facility. The computing device may correspond, for example, to the computing device 110 shown in FIG. 1.

In some example embodiments, the design layout may be a physical representation of circuits that may be transferred onto a wafer designed for a semiconductor device. In some example embodiments, the design layout may include a plurality of patterns. For example, the design layout may be provided as coordinate values of outlines of patterns constituting the design layout.

In some example embodiments, prior to manufacturing a mask based on the corrected design layout in S1350, a validation of the corrected design layout may be performed.

In some example embodiments, prior to manufacturing the mask based on the corrected design layout in S1350, optical proximity correction for the corrected design layout may be performed. The optical proximity correction may refer to correction that reflects errors due to optical proximity effects and modifying the patterns included in the corrected design layout.

In some example embodiments, in S1350, the mask may be manufactured based on data in the corrected design layout. For example, the mask may be manufactured by performing an exposure process on a mask substrate based on the data in the corrected design layout. After the exposure process, the mask may be formed by performing a series of processes such as, for example, a development, an etch, a clean, and/or a bake but is not limited thereto.

In some example embodiments, in S1360, a lithography process may be performed to fabricate the semiconductor device based on the mask. The semiconductor device may include a volatile memory such as a dynamic random-access memory (DRAM), a static random-access memory (SRAM), or a non-volatile memory such as a flash memory, or may include a logic semiconductor device such as a processor, for example, a central processing unit (CPU), a controller, or an application specific integrated circuit (ASIC). In addition to the lithography process, the semiconductor device may be further fabricated by performing a deposition process, an etch process, an ionic process, a cleaning process, or the like.

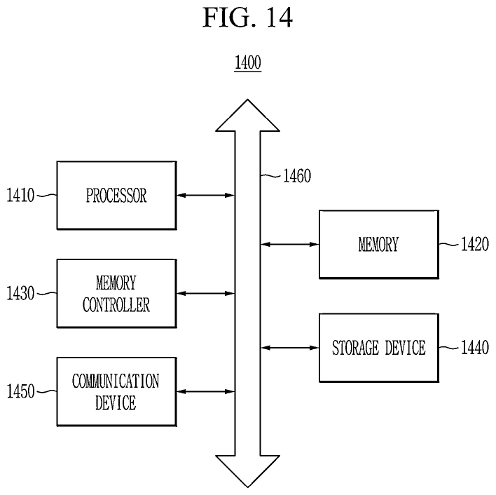

FIG. 14 is a block diagram illustrating at least one example embodiment of a computing device according to some example embodiments.

Referring to FIG. 14, a computing device 1400 may include a processor 1410, a memory 1420, a memory controller 1430, a storage device 1440, a communication interface 1450, and a bus 1460. The computing device 1400 may further include other general-purpose components.

The processor 1410 may control an overall operation of each component of the computing device 1400. The processor 1410 may be implemented as at least one of various processing units, such as a central processing unit (CPU), an application processor (AP), and a graphic processing unit (GPU).

The memory 1420 may store various data and instructions. In some embodiments, the memory 1420 may be, for example, a DRAM. The processor 1410 may execute one or more instructions loaded into the memory 1420 to perform a misalignment value estimation method and/or a design layout correction method described with reference to FIGS. 1 to 12. The memory controller 1430 may control transfers of data or commands to and from the memory 1420. In some embodiments, the memory controller 1430 may be provided as a separate chip from the processor 1410. In some embodiments, the memory controller 1430 may be provided as an internal component of the processor 1410.

The storage device 1440 may be a non-transitory machine readable medium and store programs and data. In some example embodiments, the storage device 1440 may be implemented as a non-volatile memory. In some example embodiments, the storage device 1440 may store an original design layout and/or a corrected design layout. The communication interface 1450 may support wired or wireless internet communication of the computing device 1400. Additionally, the communication interface 1450 may support various communication methods other than internet communication. In some example embodiments, the communication interface 1450 may receive the original design layout from another computing device and/or transmit a corrected design layout to another computing device. The bus 1460 may provide a communication function between the components of computing device 1400. The bus 1460 may include at least one type of bus according to a communication protocol between the components.

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While example embodiments have been described in connection with what is presently considered to be practical embodiments, it is to be understood that example embodiments are not limited to the disclosed embodiments. On the contrary, it is intended to cover various modifications and equivalent arrangements included within the spirit and scope of the appended claims.

What is claimed is:

1. A method of correcting a design layout of a semiconductor device, performed by a computing device, the method comprising:
separating a first target layer comprising a plurality of target patterns from an original design layout;
generating a second target layer by shifting the plurality of target patterns in the first target layer based on misalignment values at respective positions of the plurality of target patterns; and
combining the second target layer with the original design layout from which the first target layer is separated to generate a corrected design layout.

2. The method of claim 1, wherein the separating the first target layer comprises generating a first semiconductor cell with the first target layer, and
wherein the generating the second target layer comprises generating a second semiconductor cell by shifting the plurality of target patterns in the first semiconductor cell based on the misalignment values.

3. The method of claim 2, wherein the generating of the corrected design layout comprises disposing the second semiconductor cell in a top cell of the original design layout from which the first target layer is separated.

4. The method of claim 1, wherein the generating of the second target layer comprises generating the second target layer by shifting the plurality of target patterns in a direction that offsets misalignment by correction values, the correction values being determined based on the misalignment values at the respective positions of the plurality of target patterns.

5. The method of claim 4, further comprising:
generating data in which the respective positions of the plurality of target patterns are mapped with the misalignment values at the respective positions,
wherein the generating of the second target layer comprises shifting the plurality of target patterns based on the data.

6. The method of claim 4, further comprising:
generating data in which the respective positions of the plurality of target patterns are mapped with the correction values at the respective positions, and
wherein the generating of the second target layer comprises shifting the plurality of target patterns based on the data.

7. The method of claim 1, further comprising:
obtaining misalignment values in a plurality of regions on a wafer; and
determining the misalignment values at the respective positions of the plurality of target patterns based on the misalignment values in the plurality of regions.

8. The method of claim 7, wherein the wafer is a wafer that is taped out with a mask to which the original design layout is applied.

9. The method of claim 7, wherein the wafer is a wafer for a same generation product as the original design layout.

10. The method of claim 7, wherein the obtaining the misalignment values comprises:
measuring misalignment values in some regions among the plurality of regions using an image measurement device, and
estimating misalignment values in remaining regions among the plurality of regions based on the misalignment values in the some regions.

11. The method of claim 10, wherein the semiconductor device comprises a memory device,
wherein the memory device comprises a core region comprising the plurality of regions and a peripheral region,
wherein the some regions comprise regions adjacent to the peripheral region or a scribe lane for separating a semiconductor die from which the semiconductor device is formed.

12. The method of claim 10, wherein the estimating of the misalignment values in the remaining regions comprises:
generating an interpolation model based on the misalignment values in the some regions, and
estimating the misalignment values in the remaining regions based on the interpolation model.

13. The method of claim 12, wherein the estimating of the misalignment values in the remaining regions based on the interpolation model comprises:
calculating initial misalignment values in the remaining region based on the interpolation model, and
estimating the misalignment values in the remaining region by reflecting uniformity information on the wafer into the initial misalignment values.

14. The method of claim 1, wherein the semiconductor device comprises a memory device, and
wherein the plurality of target patterns comprises gate patterns of sub-wordline drivers of the memory device.

15. The method of claim 1, further comprising:
validating the corrected design layout by comparing a number of the plurality of target patterns in the corrected design layout with a number of the plurality of target patterns in the original design layout.

16. The method of claim 1, further comprising:
validating the corrected design layout based on a shift value between each of the plurality of target patterns in the corrected design layout and each of the plurality of target patterns in the original design layout.

17. A computing device comprising:
a memory configured to store one or more instructions; and
one or more processors configured to execute the one or more the instructions,
wherein the one or more processors are configured, by executing the one or more the instructions, to
separate a target layer comprising a plurality of target patterns from a design layout of a semiconductor device;
shift the plurality of target patterns in the target layer based on misalignment values at the plurality of target patterns; and
combine the target layer in which the plurality of target patterns are shifted with the design layout from which the target layer is separated to generate a corrected design layout.

18. The computing device of claim 17, wherein the one or more processors are further configured to:
generate a semiconductor cell comprising the target layer,
shift the plurality of target patterns in the target layer by shifting the plurality of target patterns in the semiconductor cell based on misalignment values at the plurality of target patterns; and
combine the semiconductor cell in which the plurality of target patterns are shifted with the design layout from which the target layer is separated to combine the target layer in which the plurality of target patterns are shifted with the design layout from which the target layer is separated.

19. The computing device of claim 17, wherein the processor is further configured to,
measure misalignment values in some regions among the plurality of target regions on a wafer using an image measurement device;
estimate misalignment values in remaining regions among the plurality of target regions based on the misalignment values at the some regions; and
determine the misalignment values at the plurality of target patterns based on the misalignment values in the plurality of target regions.

20. A method of fabricating a semiconductor device, comprising:
loading an original design layout;
separating a target layer comprising a plurality of target patterns from the original design layout;
shifting the plurality of target patterns in the target layer based on misalignment values;
combining the target layer in which the plurality of target patterns are shifted with the original design layout from which the target layer is separated to generate a corrected design layout;
manufacturing a mask based on the corrected design layout; and
fabricating a semiconductor device based on the mask.
